(19) United States
(12) Patent Application Publication
(10) Pub. No.: US 2024/0032357 A1
(43) Pub. Date: Jan. 25, 2024

(54) DISPLAY DEVICE, ELECTRONIC DEVICE, AND METHOD FOR DRIVING DISPLAY DEVICE

(71) Applicant: SONY SEMICONDUCTOR SOLUTIONS CORPORATION, KANAGAWA (JP)

(72) Inventor: TOKIHIRO YOKONO, KANAGAWA (JP)

(21) Appl. No.: 18/256,525

(22) PCT Filed: Dec. 17, 2021
(86) PCT No.: PCT/JP2021/046816

§ 371 Date: Jun. 8, 2023

(30) Foreign Application Priority Data
Dec. 18, 2020 (JP) 2020-210292

(51) Int. Cl. H10K 59/131; G09G 3/3233; G06F 3/01

(52) U.S. Cl. CPC H10K 59/131; G09G 3/3233; G06F 3/013; G09G 2300/0452; G09G 2354/00; G09G 2320/0261

(57) ABSTRACT

For example, a decrease in luminance in response to a change in a viewing angle is reduced. Provided is a display device including pixel parts arranged two-dimensionally. Each of the pixel parts includes a first electrode, a second electrode provided to face the first electrode and divided into a plurality of electrode parts, and an electroluminescent layer provided between the first electrode and the second electrode.

### TECHNICAL FIELD

The present disclosure relates to a display device, an electronic device, and a method for driving the display device.

### BACKGROUND ART

A display device using organic electroluminescence (EL) has been proposed. For example, Patent Document 1 below describes an organic EL display device in which a cathode electrode is divided to detect carrier balance.

### CITATION LIST

### Patent Document

Patent Document 1: Japanese Patent Application Laid-Open No. 2008-146956

### SUMMARY OF THE INVENTION

### Problems to be Solved by the Invention

In this field, it is desirable to minimize a decrease in luminance when viewed from any angular direction with respect to luminance when viewed from the front direction. The technology described in Patent Document 1 is obtained by dividing the cathode electrode in order to detect carrier balance and has been insufficient as a technology related to a decrease in luminance.

An object of the present disclosure is to minimize a decrease in luminance when viewed from any angular direction with respect to luminance when viewed from the front direction.

### Solutions to Problems

The present disclosure provides, for example,
a display device including pixel parts arranged two-dimensionally,
in which
each of the pixel parts includes
a first electrode,
a second electrode provided to face the first electrode and divided into a plurality of electrode parts, and
an electroluminescent layer provided between the first electrode and the second electrode. The present disclosure may be electronic device including the display device described above.

The present disclosure provides, for example, a method for driving a display device that includes pixel parts arranged two-dimensionally, each of the pixel parts including a first electrode, a second electrode provided to face the first electrode and divided into a plurality of electrode parts, and an electroluminescent layer provided between the first electrode and the second electrode, the method including applying a first voltage that is the same voltage as a voltage applied to the first electrode, or a second voltage that is a voltage different from the voltage applied to the first electrode, to each of the plurality of electrode parts.

### BRIEF DESCRIPTION OF DRAWINGS

FIG. 1 is a diagram that is referred to when a problem to be considered in the present disclosure is described.

FIG. 2 is a schematic diagram illustrating an overall configuration example of a display device according to one embodiment.

FIG. 3 is a diagram for explaining a square pixel arrangement.

FIG. 4 is a diagram that is referred to at the time of describing a pixel structure of a subpixel according to the embodiment.

FIG. 5 is a diagram that is referred to at the time of describing the pixel structure of the subpixel according to the embodiment.

FIG. 6 is a diagram that is referred to at the time of describing the pixel structure of the subpixel according to the embodiment.

FIGS. 7A to 7C are diagrams for explaining an example of wirings.

FIGS. 8A to 8C are diagrams for explaining an example of the wirings.

FIG. 9 is a diagram for explaining a pixel circuit included in a subpixel according to the embodiment.

FIG. 10 is a diagram illustrating a configuration example of a light-emission control circuit 70 according to the embodiment.

FIG. 11 is a block diagram illustrating a relationship between a display device according to the embodiment and an upper-level controller.

FIGS. 12A and 12B are diagrams for explaining an outline of a method for driving the display device according to the embodiment.

FIG. 13 is a view for explaining a specific example of a method for driving the display device according to the embodiment.

FIG. 14 is a flowchart illustrating the processing flow of the method for driving the display device according to the embodiment.

FIGS. 15A and 15B are diagrams referred to at the time of describing an effect obtained by the embodiment.

FIGS. 16A and 16B are diagrams referred to at the time of describing the effect obtained by the embodiment.

FIGS. 17A to 17D are diagrams for explaining a modification.

FIGS. 18A to 18D are diagrams for explaining a modification.

FIGS. 19A and 19B are diagrams for explaining an application example.

FIG. 20 is a diagram for explaining an application example.

FIG. 21 is a diagram for explaining an application example.

### MODE FOR CARRYING OUT THE INVENTION

Hereinafter, an embodiment and the like of the present disclosure will be described with reference to the drawings. Note that a description will be made in the following order:

<Problem to be considered in embodiment>

<One Embodiment>

<Modification>

<Application Example>

The embodiment and the like described below are preferred specific examples of the present disclosure, and the content of the present disclosure is not limited to these embodiments and the like.

### Problem to be Considered in the Present Disclosure

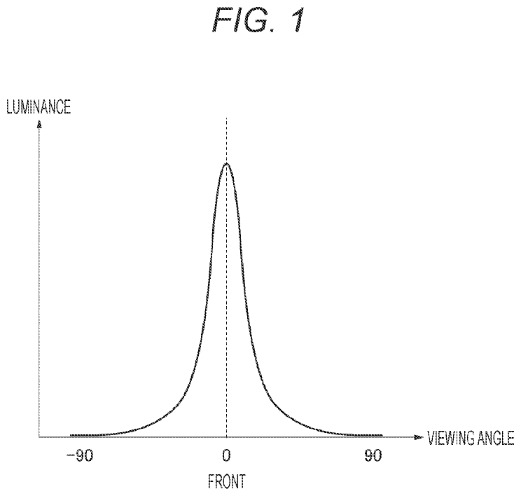

First, a problem to be considered in the present disclosure will be described in order to facilitate understanding of the present disclosure. As illustrated in FIG. 1, in general, in a display such as a micro-organic light-emitting diode (M-OLED), luminance with respect to the front direction is maximum, and the luminance decreases as an angle from the front direction to the peripheral direction increases. Hence it has been impossible to make the luminance when viewed from any angular direction the same as the luminance when viewed from the front direction. In addition, it has been difficult to satisfy specifications required for a viewing angle, that is, specifications related to luminance to be maintained at a position shifted by a predetermined angle from the front direction. In light of the above, details of the present disclosure will be described using an embodiment.

### One Embodiment

[Configuration Example of Display Device]

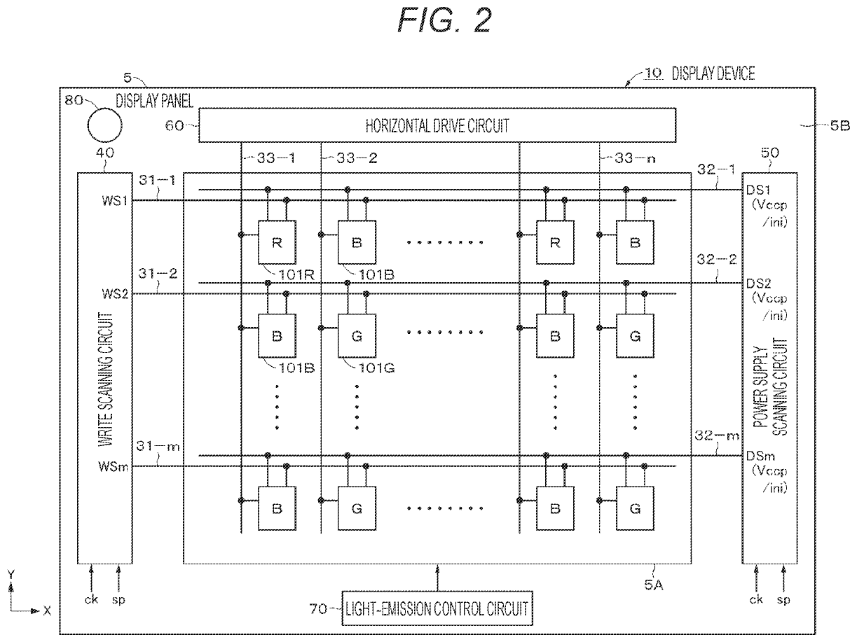

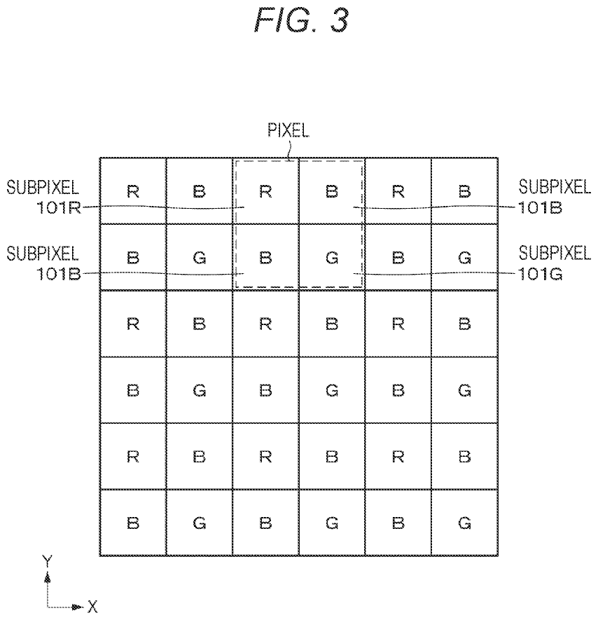

A configuration example of a display device (display device according to one embodiment of the present disclosure will be described with reference to FIGS. 2 and 3. FIG. 2 is a schematic diagram illustrating an overall configuration example of the display device 10. FIG. 3 is a diagram for explaining a square pixel arrangement. In the following description, the horizontal direction and the vertical direction of the display surface of the display device 10 may be referred to as the X-axis direction and the Y-axis direction, respectively, and the thickness direction of the display device 10 may be referred to as the Z-axis direction.

In the present embodiment, as an example of the display device 10, an active matrix-type organic EL display device will be described, the display device using a current-driven electro-optical element, for example, an organic EL element (organic field light-emitting element) in which light-emission luminance changes in accordance with a value of a current flowing through the device as a light-emitting element of a pixel. The display device 10 may be a micro-display or may be included in a virtual reality (VR) device, a mixed reality (MR) device, an augmented reality (AR) device, an electronic viewfinder (EVF), a small projector, or the like.

The display device 10 includes a display panel 5, and the display panel 5 includes a display area 5A and a peripheral area provided on a peripheral edge of the display area 5A. In the display area 5A, a plurality of subpixels 101R, 101G, 101B is two-dimensionally arranged in an arrangement pattern.

Specifically, as illustrated in FIG. 3, the plurality of subpixels 101R, 101G, 101B is two-dimensionally arranged in a matrix or the like. The subpixel 101R displays red, the subpixel 101G displays green, and the subpixel 101B displays blue. For example, one pixel includes one subpixel 101R, one subpixel 101G, and two subpixels 101B arranged in a square shape. Note that in the following description, the subpixels 101R, 101G, 101B will be referred to as subpixels 101 unless otherwise distinguished. Each subpixel 101 corresponds to a pixel part. Further, FIG. 3 illustrates an example of the square pixel arrangement of the subpixels 101, and the number and arrangement of the subpixels 101 are not limited to those illustrated in FIG. 3.

In the peripheral area 5B, a drive circuit and a power supply circuit (hereinafter referred to collectively as a drive circuit and the like as appropriate) that drive each subpixel 101 are provided. The drive circuit and the like include, for example, a write scanning circuit 40, a power supply scanning circuit 50, a horizontal drive circuit 60, and a light-emission control circuit 70.

For the pixel arrangement of m rows and n columns in the display area 5A, scanning lines 31-1 to 31-m and power supply lines 32-1 to 32-m are wired for the respective pixel rows, and signal lines 33-1 to 33-n are wired for the respective pixel columns.

The display area 5A is usually formed on a transparent insulating substrate such as a glass substrate and has a planar (flat) panel structure. Each subpixel 101 of the display area 5A can be formed using an amorphous silicon thin film transistor (TFT) or a low-temperature polysilicon TFT. In a case where the low-temperature polysilicon TFT is used, the write scanning circuit 40, the power supply scanning circuit 50, the horizontal drive circuit 60, and the light-emission control circuit 70 can also be mounted on the display panel (substrate) forming the display area 5A.

The write scanning circuit 40 includes a shift register or the like that sequentially shifts (transfers) a start pulse sp in synchronization with a clock pulse ck, and sequentially performs scanning (line sequential scanning) on each subpixel 101 of the display area 5A in units of rows by sequentially supplying writing pulses (scanning signals) WS1 to WSm to the scanning lines 31-1 to 31-m at the time of writing a video signal to each subpixel 101 of the display area 5A.

The power supply scanning circuit 50 includes a shift register or the like that sequentially shifts a start pulse sp in synchronization with a clock pulse ck, and supplies power supply line potentials DS1 to DSm switched between a first potential Vccp and a second potential Vini lower than the first potential Vccp to the power supply lines 32-1 to 32-m in synchronization with the line sequential scanning by the write scanning circuit 40, thereby controlling the light emission/non-light emission of the subpixel 101.

The horizontal drive circuit 60 appropriately selects either a signal voltage (hereinafter may be simply described as “signal voltage”) Vsig of a video signal corresponding to luminance information supplied from a signal supply source (not illustrated) or an offset voltage Vofs, and writes the signal voltage Vsig or the offset voltage Vofs to each subpixel 101 of the display area 5A through signal lines 33-1 to 33-n, for example, in units of rows. That is, the horizontal drive circuit adopts a drive form of line sequential writing in which the signal voltage Vsig of the video signal is written in units of rows (lines).

Here, the offset voltage Vofs is a reference voltage (e.g., a voltage corresponding to a black level) serving as a reference of the signal voltage Vsig of the video signal. Further, the second potential Vini is set to a potential lower than the offset voltage Vofs, for example, a potential lower than Vofs−Vth, preferably a potential sufficiently lower than Vofs−Vth, when a threshold voltage of a drive transistor 25 is Vth.

The light-emission control circuit 70 is a circuit that applies a predetermined voltage to divided cathode parts in one subpixel 101. Note that a specific configuration example of the light-emission control circuit 70 will be described later.

In the peripheral area 5B, a sensor 80 is further provided. The sensor 80 is a sensor that detects a user viewing the display device 10. The sensor 80 is, for example, a sensor that images the user's eye (pupil) and detects the line-of-sight direction of the user by using the image of the eye. The sensor includes, for example, a camera unit that images the user's eye and a unit that detects the user's line-of-sight direction. The camera unit may include a light-emitting unit that emits infrared light or the like.

As a method of detecting the line-of-sight direction of the user, a known method can be applied. For example, it is possible to apply a corneal reflection method in which infrared light or the like is emitted from a light-emitting unit and reflection from the cornea is used to detect the line-of-sight direction of the user on the basis of the position of the pupil by a unit that detects the line-of-sight direction. Further, for example, a method may be applied to recognize a motionless point such as the inner or outer corner of the eye by image recognition and estimate the line-of-sight direction from the position of the iris of the eye.

[Pixel Structure]

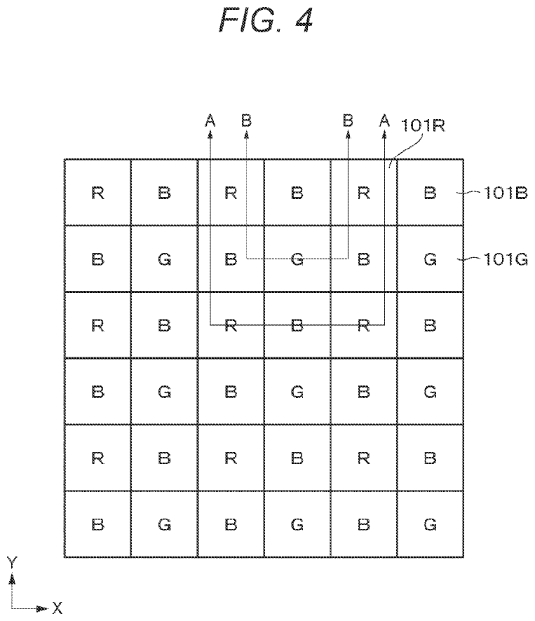

Next, details of the pixel structure of the subpixel 101 will be described. As described above, in the display area 5A of the display device 10, as illustrated in FIG. 4, the plurality of subpixels 101R, 101G, 101B is two-dimensionally arranged in a prescribed arrangement pattern such as a matrix.

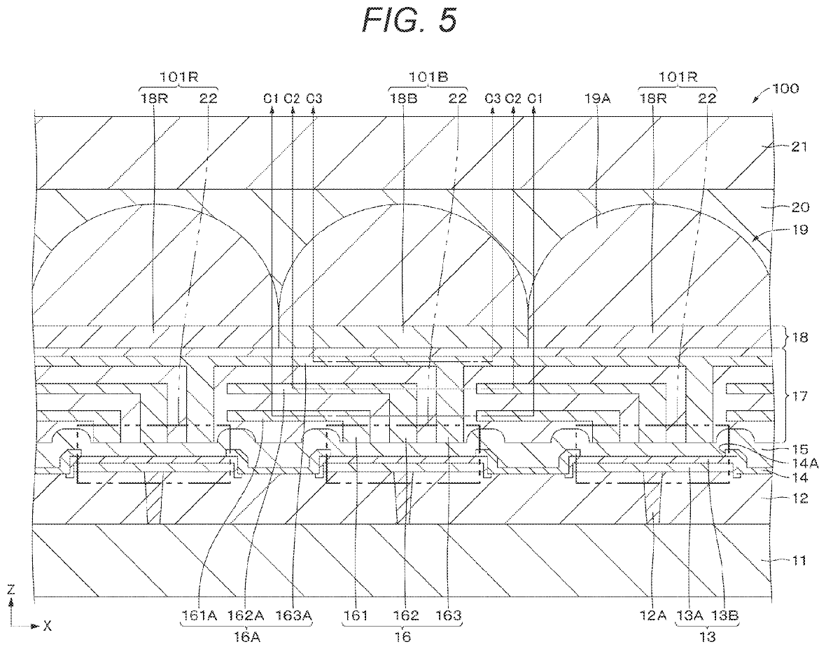

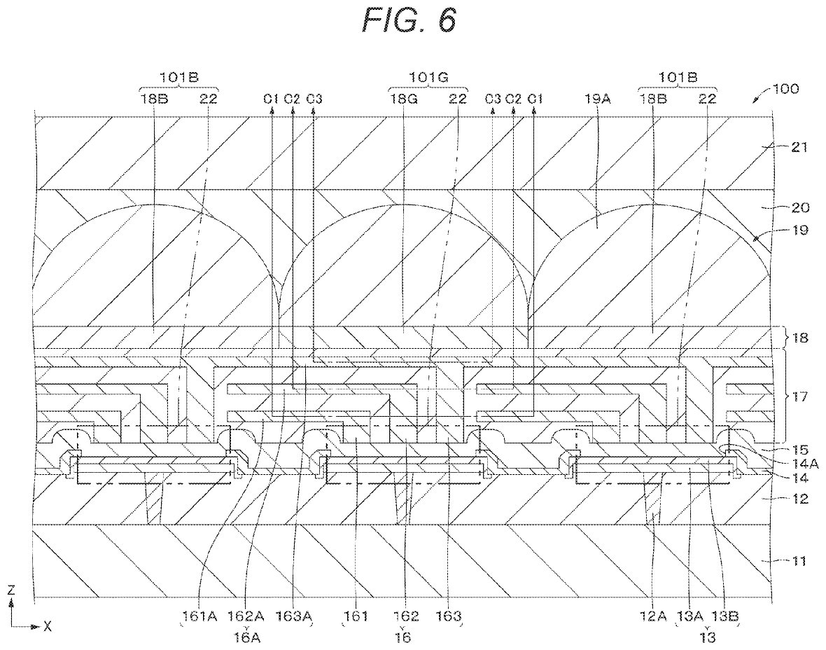

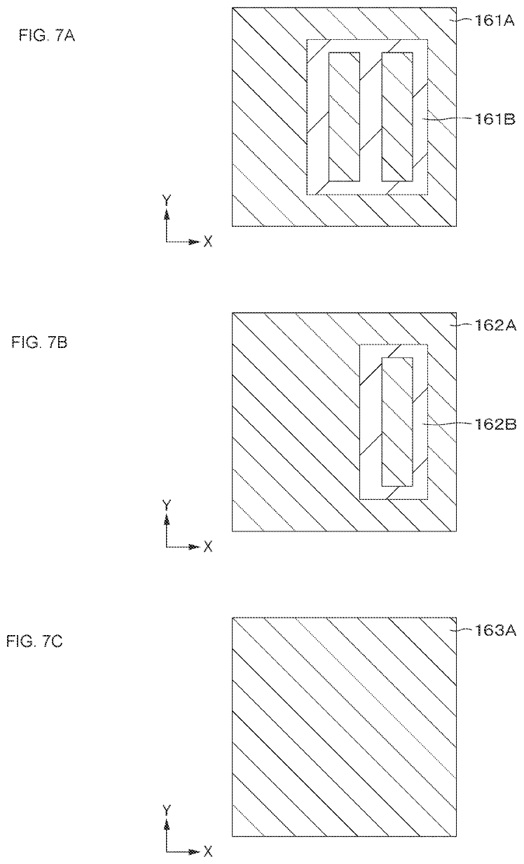

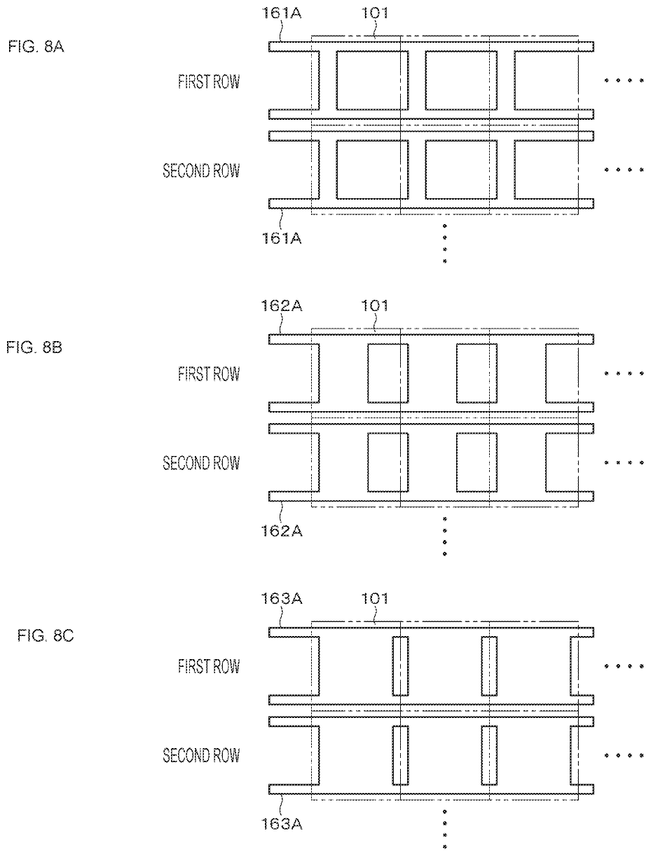

FIG. 5 is a cross-sectional view taken along line A-A in FIG. 4. FIG. 6 is a cross-sectional view taken along line B-B in FIG. 4. The display device 10 includes a drive substrate 11, an interlayer insulating layer 12, a plurality of anodes (first electrodes) 13, an inter-element insulating layer 14, an organic electroluminescent layer (hereinafter referred to as “organic EL layer”) 15, a protective layer 17, a color filter 18, a lens array 19, a filling resin layer 20, and a counter substrate 21. In the protective layer 17, a plurality of cathodes (second electrodes) 16 and a plurality of wiring groups 16A are provided.

The display device 10 is a top emission type display device. The counter substrate 21 side of the display device 10 is the top side (display surface side), and the drive substrate 11 side of the display device 10 is the bottom side. In the following description, in each layer constituting the display device 10, a surface on the top side of the display device 10 is referred to as a first surface, and a surface on the bottom side of the display device 10 is referred to as a second surface.

Each of the subpixels 101R, 101G, 101B includes a light-emitting element 22. The light-emitting element 22 is a so-called organic EL element. The light-emitting element 22 is configured to emit white light. The light-emitting element 22 includes the anode 13, the organic EL layer 15, and the cathode 16. In the present embodiment, as a coloring method, a method using the white light-emitting element 22 and the color filter 18 is used.

(Drive Substrate)

The drive substrate 11 is a so-called backplane. The drive substrate 11 is provided with a drive circuit that drives the plurality of light-emitting elements 22, a power supply circuit that supplies power to the plurality of light-emitting elements 22, and the like (none of which are illustrated).

The substrate body of the drive substrate 11 may include, for example, a semiconductor from which a transistor or the like is easy to form, or may include glass or resin having low moisture and oxygen permeability. Specifically, the substrate body may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from the group consisting of polymethyl methacrylate, polyvinyl alcohol, polyvinyl phenol, polyether sulfone, polyimide, polycarbonate, polyethylene terephthalate, polyethylene naphthalate, and the like.

(Interlayer Insulating Layer)

The interlayer insulating layer 12 (hereinafter referred to simply as “insulating layer 12”) is provided on the first surface of the drive substrate 11 and covers the drive circuit, the power supply circuit, and the like. Thereby, the first surface of the drive substrate 11 is flattened. The insulating layer 12 insulates the drive substrate 11 and the plurality of anodes 13 from each other. The insulating layer 12 includes a plurality of contact plugs 12A and a plurality of wirings (not illustrated). The plurality of contact plugs 12A electrically connects the anode 13 and the drive circuit.

The insulating layer 12 may have a single-layer structure or a laminated structure. The insulating layer 12 may be an organic insulating layer, an inorganic insulating layer, or a laminate of these layers. The organic insulating layer contains, for example, at least one selected from the group consisting of a polyimide-based resin, an acrylic resin, a novolac-based resin, and the like. The inorganic insulating layer contains, for example, at least one selected from the group consisting of silicon oxide (SiOₓ), silicon nitride (SiNₓ), silicon oxynitride (SiOₓN_{y}), and the like.

(Anode)

The plurality of anodes 13 is two-dimensionally arranged on the first surface of the insulating layer 12 in an arrangement pattern similar to that of the plurality of subpixels 101. When a voltage is applied between the anode 13 and the cathode 16, holes are injected from the anode 13 into the organic EL layer 15. The adjacent anodes 13 are electrically separated from each other by the inter-element insulating layer 14. The anode 13 includes a metal layer 13A and a transparent conductive layer 13B in this order on the first surface of the insulating layer 12. The transparent conductive layer 13B may cover the side surface of the metal layer 13A.

The metal layer 13A has a function as a reflective layer that reflects light emitted from the organic EL layer 15. The metal layer 13A contains, for example, at least one metal element selected from the group consisting of aluminum (Al), silver (Ag), chromium (Cr), gold (Au), platinum (Pt), nickel (Ni), copper (Cu), molybdenum (Mo), magnesium (Mg), iron (Fe), and tungsten (W). The metal layer 13A may contain at least one metal element described above as a constituent element of the alloy. Specific examples of the alloy include an aluminum alloy, a silver alloy, and the like. Specific examples of the aluminum alloy include, for example, AlNd, AlCu, and the like. From the viewpoint of improving the reflectance, the metal layer 13A preferably contains at least one metal element selected from the group consisting of aluminum (Al) and silver (Ag) among the above metal elements.

An underlying layer (not illustrated) may be provided adjacent to the second surface side of the metal layer 13A. The underlying layer is for improving the crystal orientation of the metal layer 13A at the time of formation of the metal layer 13A. The underlying layer contains, for example, at least one metal element selected from the group consisting of titanium (Ti) and tantalum (Ta). The underlying layer may contain at least one metal element described above as a constituent element of the alloy.

The work function of the transparent conductive layer 13B is preferably higher than the work function of the metal layer 13A. In this case, the hole injection property from the anode 13 to the organic EL layer 15 can be improved. The transparent conductive layer 13B preferably has high transmittance from the viewpoint of improving light-emission efficiency. The transparent conductive layer 13B contains a transparent conductive oxide (TOO). The transparent conductive oxide contains, for example, at least one selected from the group consisting of a transparent conductive oxide containing indium (hereinafter referred to as “indium-based transparent conductive oxide”), a transparent conductive oxide containing tin (hereinafter referred to as “tin-based transparent conductive oxide”), and a transparent conductive oxide containing zinc (hereinafter referred to as “zinc-based transparent conductive oxide”).

The indium-based transparent conductive oxide includes, for example, indium tin oxide (ITO), indium zinc oxide (IZO), indium gallium oxide (IGO), or indium gallium zinc oxide (IGZO) fluorine-doped indium oxide (IFO). Among these transparent conductive oxides, indium tin oxide (ITO) is particularly preferable. This is because indium tin oxide (ITO) has a particularly low barrier for hole injection into the organic EL layer 15 in terms of work function, so that the drive voltage of the display device 10 can be particularly reduced. The tin-based transparent conductive oxide contains, for example, tin oxide, antimony-doped tin oxide (ATO), or fluorine-doped tin oxide (FTC). The zinc-based transparent conductive oxide includes, for example, zinc oxide, aluminum-doped zinc oxide (AZO), boron-doped zinc oxide, or gallium-doped zinc oxide (GZO).

(Inter-Element Insulating Layer)

The inter-element insulating layer 14 (hereinafter referred to simply as “insulating layer 14”) is provided in a portion between the adjacent anodes 13 in the first surface of the insulating layer 12. The insulating layer 14 insulates the adjacent anodes 13 from each other. The insulating layer 14 has a plurality of openings 14A. The plurality of openings 14A is provided corresponding to the respective subpixels 101. More specifically, each of the plurality of openings 14A is provided on the first surface (the surface on the organic EL layer 15 side) of each anode 13. The anode 13 and the organic EL layer 15 are in contact with each other through the opening 14A.

As the constituent material of the insulating layer 14, a material similar to that of the insulating layer 12 described above can be exemplified.

(Organic EL Layer)

The organic EL layer 15 is provided between the plurality of anodes 13 and the plurality of cathodes 16. The organic EL layer 15 is continuously provided over all the subpixels 101 in the display area and is provided as a layer common to all the subpixels 101 in the display area.

The organic EL layer 15 is configured to emit white light. The organic EL layer 15 may be an organic EL layer with a one-stack structure including a single-layer light-emitting unit, an organic EL layer with a two-stack structure including a two-layer light-emitting unit, or an organic EL layer with a structure other than these. The organic EL layer with a one-stack structure has a configuration in which, for example, a hole injection layer, a hole transport layer, a red light-emitting layer, a light-emission separation layer, a blue light-emitting layer, a green light-emitting layer, an electron transport layer, and an electron injection layer are laminated in this order from the anode 13 toward the cathode 16. The organic EL layer with a two-stack structure has a configuration in which, for example, a hole injection layer, a hole transport layer, a blue light-emitting layer, an electron transport layer, a charge generation layer, a hole transport layer, a yellow light-emitting layer, an electron transport layer, and an electron injection layer are laminated in this order from the anode 13 toward the cathode 16.

The hole injection layer is for enhancing hole injection efficiency into each light-emitting layer and preventing leakage. The hole transport layer is for enhancing the hole transport efficiency to each light-emitting layer. The electron injection layer is for increasing electron injection efficiency into each light-emitting layer. The electron transport layer is for enhancing electron transport efficiency to each light-emitting layer. The light-emission separation layer is a layer for adjusting the injection of carriers into each light-emitting layer, and the light-emission balance of each color is adjusted by injecting electrons or holes into each light-emitting layer through the light-emission separation layer. The charge generation layer supplies electrons and holes to two light-emitting layers sandwiching the charge generation layer.

The red light-emitting layer, the green light-emitting layer, the blue light-emitting layer, and the yellow light-emitting layer generate red light, green light, blue light, and yellow light, respectively, by application of an electric field, causing recombination between holes injected from the anode 13 and electrons injected from the cathode 16.

(Protective Layer)

The protective layer 17 is provided on the first surface of the organic EL layer 15. The protective layer 17 shields the organic EL layer 15 from the outside air and prevents the entry of moisture and the like from the external environment into the light-emitting element 22. As described above, the plurality of cathodes 16 and the wiring group 16A are provided in the protective layer 17.

The protective layer 17 contains, for example, an inorganic material or a polymer resin having low hygroscopicity. The protective layer 17 may have a single-layer structure or a multi-layer structure. The inorganic material includes, for example, at least one selected from the group consisting of silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from the group consisting of a thermosetting resin, an ultraviolet curable resin, and the like.

(Cathode)

The plurality of cathodes 16 is two-dimensionally arranged on the first surface of the organic EL layer 15 in an arrangement pattern similar to that of the plurality of subpixels 101. The cathode 16 faces the first surface of the anode 13 with the organic EL layer 15 interposed therebetween. The cathode 16 includes a first cathode part 161, a second cathode part 162, and a third cathode part 163, which are formed by dividing an area. The first cathode part 161, the second cathode part 162, and the third cathode part 163 face a first area, a second area, and a third area of the first surface of the anode 13, respectively, with the organic EL layer 15 interposed therebetween. In the present embodiment, the first cathode part 161, the second cathode part 162, and the third cathode part 163 correspond to electrode parts included in the cathode 16, respectively.

The first cathode part 161, the second cathode part 162, and the third cathode part 163 are provided in this order in the horizontal direction of the display device 10 (X-axis direction). That is, the first cathode part 161 is provided near the left side (near the right side when viewed from the user), the second cathode part 162 is provided near the center (near the center when viewed from the user), and the third cathode part 163 is provided near the right side (near the left side when viewed from the user). The first cathode part 161 and the second cathode part 162 adjacent to each other, and the second cathode part 162 and the third cathode part 163 adjacent to each other, are separated from each other. Each of the first cathode part 161, the second cathode part 162, and the third cathode part 163 is exposed from the second surface of the protective layer 17 and is in contact with the second surface of the organic EL layer 15.

When a voltage is applied between the anode 13 and the first cathode part 161, electrons are injected from the first cathode part 161 into the organic EL layer 15. When a voltage is applied between the anode 13 and the second cathode part 162, electrons are injected from the second cathode part 162 into the organic EL layer 15. When a voltage is applied between the anode 13 and the third cathode part 163, electrons are injected from the third cathode part 163 into the organic EL layer 15.

The first cathode part 161, the second cathode part 162, and the third cathode part 163 are transparent electrodes having permeability to light generated in the organic EL layer 15. Here, the transparent electrode also includes a semi-permeable reflective layer. Each of the first cathode part 161, the second cathode part 162, and the third cathode part 163 preferably includes a material having as high permeability as possible and a small work function in order to enhance light-emission efficiency.

Each of the first cathode part 161, the second cathode part 162, and the third cathode part 163 includes, for example, a metal or a metal oxide. The metal contains, for example, at least one selected from the group consisting of magnesium (Mg), aluminum (Al), silver (Ag), calcium (Ca), and sodium (Na). The metal may be an alloy containing at least one of the above. Specific examples of the alloy include a MgAg alloy, a MgAl alloy, an AlLi alloy, and the like. The metal oxide is a transparent conductive oxide. As the transparent conductive oxide, a material similar to the transparent conductive oxide of the transparent conductive layer 13B described above can be exemplified.

(Wiring Group)

The plurality of wiring groups 16A extends in the horizontal direction of the display device 10 (X-axis direction) and is arranged at a prescribed pitch in the vertical direction of the display device 10 (Y-axis direction). The wiring group 16A includes a first wiring 161A, a second wiring 162A, and a third wiring 163A provided in different layers. The first wiring 161A, the second wiring 162A, and the third wiring 163A are connected to the first cathode part 161, the second cathode part 162, and the third cathode part 163, respectively.

The first wiring 161A, the second wiring 162A, and the third wiring 163A are disposed to overlap each other in the thickness direction of the protective layer 17 (Z-axis direction). More specifically, the first wiring 161A, the second wiring 162A, and the third wiring 163A are arranged in this order from the second surface of the protective layer 17 toward the first surface. In the present embodiment, each of the first wiring 161A, the second wiring 162A, and the third wiring 163A corresponds to a wiring part. The first wiring 161A and the second wiring 162A, and the second wiring 162A and the third wiring 163A, which are adjacent in the thickness direction of the protective layer 17 (Z-axis direction), are separated from each other.

(Color Filter)

The color filter 18 is provided on the first surface of the protective layer 17. The color filter 18 includes a red filter 17R, a green filter 17G, and a blue filter 17B. Each of the red filter 17R, the green filter 17G, and the blue filter 17B is provided to face the light-emitting element 22. The red filter 17R and the light-emitting element 22 constitute a subpixel 101R, the green filter 17G and the light-emitting element 22 constitute a subpixel 101G, and the blue filter 17B and the light-emitting element 22 constitute a subpixel 101B.

(Lens Array)

The lens array 19 is for improving the light extraction efficiency of the display device 10. The lens array 19 is provided on the first surface of the color filter 18. The lens array 19 includes a plurality of lenses 19A. The plurality of lenses 19A is two-dimensionally arranged in a prescribed arrangement pattern on the first surface of the color filter 18. One lens 19A may be provided for one subpixel 101, or two or more lenses 19A may be provided for one subpixel 101. The lens 19A has, for example, a dome shape, a truncated cone shape, or some other shape.

(Filling Resin Layer)

The filling resin layer 20 is filled between the lens array 19 and the counter substrate 21. The filling resin layer 20 has a function as an adhesive layer for bonding the lens array 19 and the counter substrate 21. The filling resin layer 20 contains, for example, at least one selected from the group consisting of a thermosetting resin, an ultraviolet curable resin, and the like.

(Counter Substrate)

The counter substrate 21 is provided to face the drive substrate 11. The counter substrate 21 seals the light-emitting element 22, the color filter 18, and the like. The counter substrate 21 includes a material such as glass transparent to each color light emitted from the color filter 18.

“Details of Wiring Group”

Next, details of the wiring group 16A will be described with reference to FIGS. 7 and 8. The first wiring 161A, the second wiring 162A, and the third wiring 163A are provided in different layers.

FIG. 7A is a cross-sectional view taken along line C1-C1 in FIG. 5 or 6. FIG. 7B is a cross-sectional view taken along line C2-C2 in FIG. 5 or 6. FIG. 7C is a cross-sectional view taken along line C3-C3 in FIG. 5 or 6.

As illustrated in FIG. 7A, the first wiring 161A includes a via 161B. Further, as illustrated in FIG. 7B, the second wiring 162A includes via 162B. As illustrated in FIG. 7C, no via is formed in the third wiring 163A. The via 161B and the via 162B are formed to prevent contact between the wirings.

Each of the first wiring 161A, the second wiring 162A, and the third wiring 163A has a solid shape (a shape uniformly formed in a planar shape) except for the via. This makes it possible to realize a reduction in the resistance of each wiring.

As illustrated in FIGS. 8A to 8C, the wiring group 16A is provided for each line. Specifically, the first wiring 161A, the second wiring 162A, and the third wiring 163A are provided for each line. Note that FIGS. 8A to 8C are views of the respective wirings as viewed from above, and other wirings are partially illustrated for easy understanding.

[Pixel Circuit]

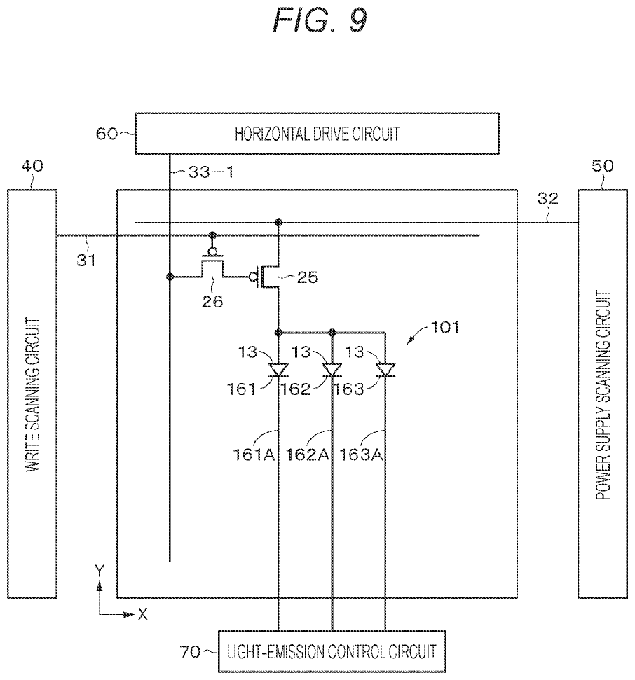

Next, a pixel circuit included in the subpixel 101 will be described. FIG. 9 is a circuit diagram illustrating a specific configuration example of the pixel circuit included in the subpixel 101 in the display device 10.

As illustrated in FIG. 9, the subpixel 101 includes a drive transistor 25 and a write transistor 26. Further, as described above, the subpixel 101 includes the first cathode part 161, the second cathode part 162, and the third cathode part 163. Note that for the sake of illustration, the anode 13 is also illustrated as divided in FIG. 9, but is actually a common (not divided) anode in one subpixel.

In the present embodiment, p-channel TFTs are used as the drive transistor 25 and the write transistor 26. However, the combination of the conductivity types of the drive transistor 25 and the write transistor 26 here is merely an example, and the combination is not limited thereto.

The anode 13 of the subpixel 101 is connected to the drain electrode of the drive transistor 25. Further, the first cathode part 161 is connected to the light-emission control circuit 70 through the first wiring 161A. The second cathode part 162 is connected to the light-emission control circuit 70 through the second wiring 162A. The third cathode part 163 is connected to the light-emission control circuit 70 through the third wiring 163A.

The drive transistor 25 has a drain electrode connected to the anode 13 and a source electrode connected to a power supply line 32 (32-1 to 32-m).

The write transistor 26 has a gate electrode connected to the scanning line 31 (31-1 to 31-m), one electrode (source electrode/drain electrode) connected to the signal line 33 (33-1 to 33-n), and the other electrode (drain electrode/source electrode) connected to the gate electrode of the drive transistor 25.

In the above configuration, the write transistor 26 becomes conductive in response to a scanning signal WS applied from the write scanning circuit 40 to the gate electrode through the scanning line 31, thereby sampling the signal voltage Vsig or the offset voltage Vofs of the video signal corresponding to the luminance information supplied from the horizontal drive circuit 60 through the signal line 33 and writing the signal voltage Vsig or the offset voltage Vofs into the subpixel 101.

The written signal voltage Vsig or offset voltage Vofs is applied to the gate electrode of the drive transistor 25. When the potential DS of the power supply line 32 (32-1 to 32-m) is at the first potential Vccp, the drive transistor 25 receives supply of a current from the power supply line 32, supplies a drive current having a current value corresponding to the voltage value of the signal voltage Vsig to the light-emitting element 22, and drives the light-emitting element 22 with a current to emit light.

The light-emission control circuit 70 controls a voltage applied to each of the first cathode part 161, the second cathode part 162, and the third cathode part 163. This causes a predetermined area to selectively emit light in the subpixel 101.

Note that the subpixel 101 may include a capacitor (holding capacitance) having one electrode connected to the gate electrode of the drive transistor 25 and the other electrode connected to the drain electrode of the drive transistor 25.

[Light-Emission Control Circuit]

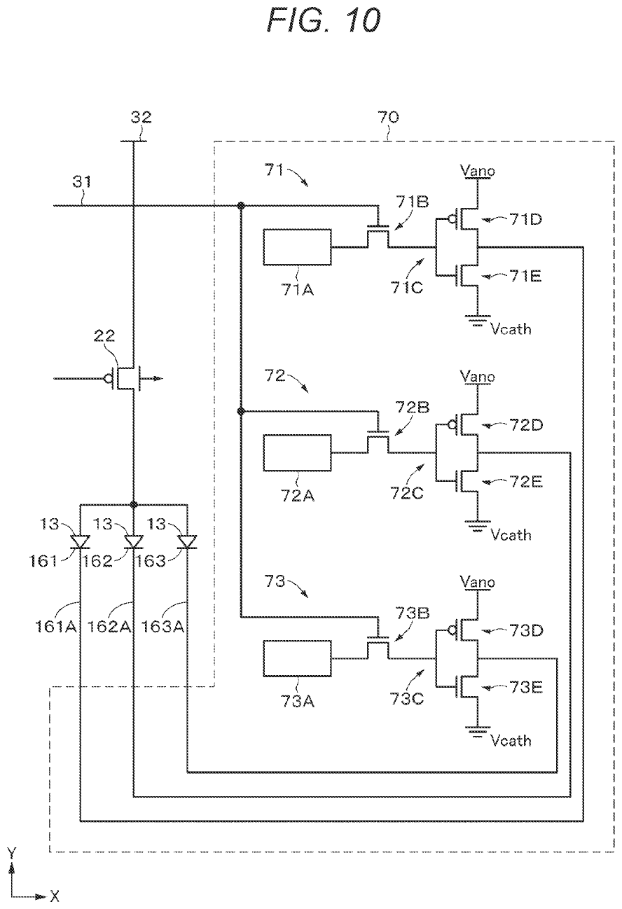

Next, details of the light-emission control circuit 70 will be described. The light-emission control circuit 70 includes a number of circuit parts corresponding to the number of divisions of the cathode. In the present embodiment, the light-emission control circuit 70 includes three circuit parts (circuit part 71, 72, 73). As illustrated in FIG. 10, the circuit part 71 includes a pulse generation circuit 71A, an n-channel FET 71B which is an example of a switching element, and an inverter circuit 71C connected in series with the FET 71B. The inverter circuit 71C has a configuration in which a p-channel FET 71D and an n-channel FET 71E are connected in series.

The pulse generation circuit 71A generates a pulse to be applied to the inverter circuit 71C. The FET 71B has a gate electrode connected to the scanning line 31 (31-1 to 31-m), and one electrode (source electrode/drain electrode) connected to the input side of the inverter circuit 71C (the gate of the FET 71D and the gate of the FET 71E).

The source electrode of the FET 71D constituting the inverter circuit 71C is connected to a predetermined voltage Vano (hereinafter also referred to simply as Vano.). Further, the source electrode of the FET 71E constituting the inverter circuit 71C is connected to a predetermined voltage Vcath ((hereinafter also referred to simply as Vcath). Here, Vano is a voltage corresponding to a first voltage and means the same voltage as the voltage applied to the anode 13 (a voltage at which the current flowing between the anode and the cathode becomes negligibly small). Further, Vcath is a voltage corresponding to a second voltage and means a voltage different from the voltage applied to the anode 13 (a voltage at which a current flows between the anode and the cathode and the organic EL layer emits light).

The output side of the inverter circuit 71C (the connection point between the FET 71D and the FET 71E) is connected to one of the divided cathode electrodes, specifically, the first wiring 161A connected to the first cathode part 161.

The circuit part 72 and the circuit part 73 also have similar configurations as that of the circuit part 71. Schematically described, the circuit part 72 includes a pulse generation circuit 72A, an n-channel FET 72B which is an example of a switching element, and an inverter circuit 72C connected in series with the FET 72B. The inverter circuit 72C has a configuration in which a p-channel FET 72D and an n-channel FET 72E are connected in series. The output side of the inverter circuit 72C (the connection point between the FET 72D and the FET 72E) is connected to one of the divided cathode electrodes, specifically, the second wiring 162A connected to the second cathode part 162.

The circuit part 73 includes a pulse generation circuit 73A, an n-channel FET 73B as an example of a switching element, and an inverter circuit 73C connected in series with the FET 73B. The inverter circuit 73C has a configuration in which a p-channel FET 73D and an n-channel FET 73E are connected in series. The output side of the inverter circuit 73C (the connection point between the FET 73D and the FET 73E) is connected to one of the divided cathode electrodes, specifically, the third wiring 163A connected to the third cathode part 163. That is, the light-emission control circuit 70 is configured to be able to apply a different voltage to each of the first wiring 161A, the second wiring 162A, and the third wiring 163A.

[Operation Example of Display Device]

(Overview)

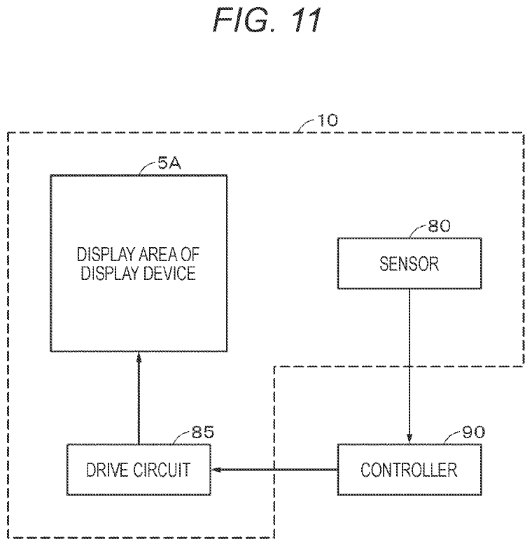

Next, an operation example of the display device 10 will be described. As illustrated in FIG. 11, the display device 10 is connected to a controller 90 that is a high-order integrated circuit (IC). The display device 10 and the controller 90 are connected through flexible printed circuits (FPC) or the like. Note that a drive circuit 85 illustrated in FIG. 11 is a collective term for the write scanning circuit 40, the power supply scanning circuit 50, the horizontal drive circuit 60, and the light-emission control circuit 70.

A sensing result by the sensor 80 of the display device 10 is supplied to the controller 90. The controller 90 determines an area to be caused to emit light in the subpixel 101 in accordance with the sensing result of the sensor 80, for example, the line-of-sight direction of the user. Specifically, the controller 90 determines an area corresponding to the line-of-sight direction as an area to be caused to emit light. The controller 90 controls the light-emission control circuit 70 so that the determined area emits light. Note that in the present embodiment, the controller 90 is illustrated as a configuration different from the display device 10, but the display device 10 may include the controller 90.

The light-emission control circuit 70 operates in accordance with the control of the controller 90. When the light-emission control circuit 70 operates, the area determined by the controller 90 emits light. For example, as illustrated in FIG. 12A, in a case where the vicinity of the center of the subpixel 101 is caused to emit light, Vcath is applied to the second cathode part 162 in the vicinity of the center of the subpixel 101. This allows a current to flow between the second cathode part 162 and the anode 13, and the organic EL layer 15 interposed therebetween emits light. Further, for example, as illustrated in FIG. 12B, in a case where the vicinity of the left of the subpixel 101 (the vicinity of the right when viewed from the user) is caused to emit light, Vcath is applied to the first cathode part 161 in the vicinity of the left of the subpixel 101. This allows a current to flow between the first cathode part 161 and the anode 13, and the organic EL layer 15 interposed therebetween emits light.

(Driving Method)

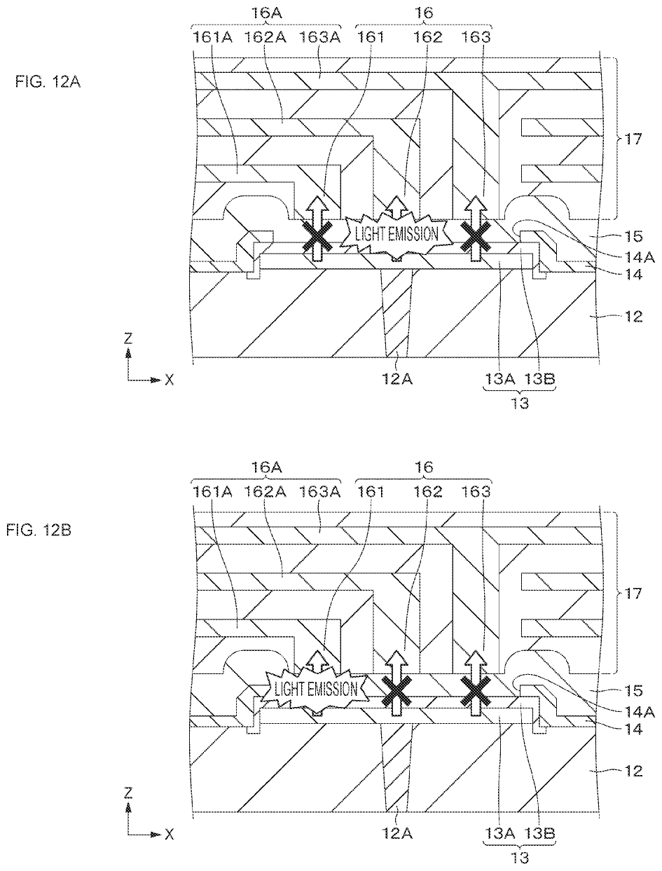

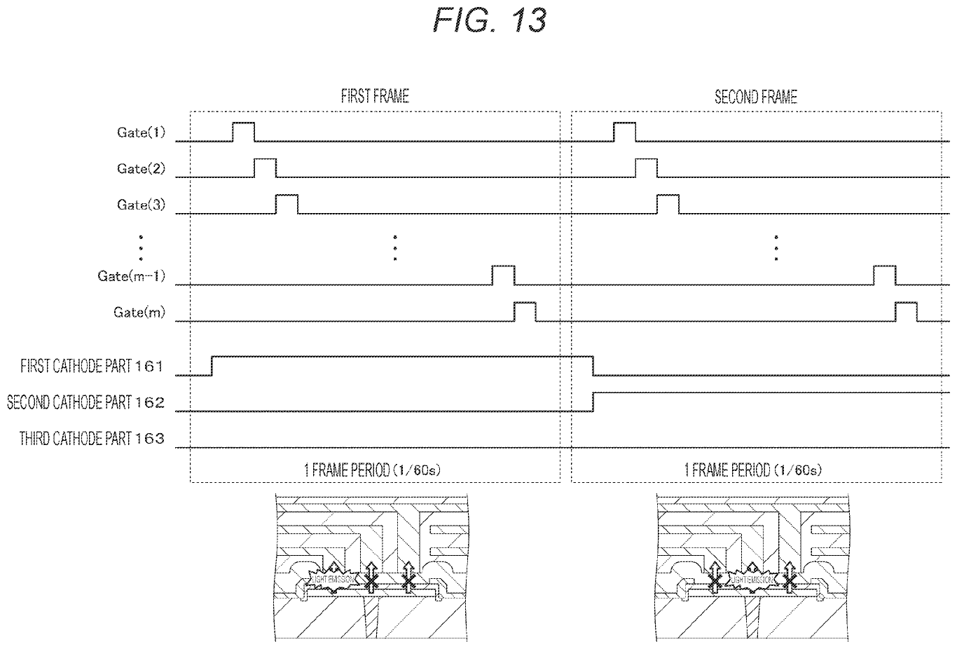

A specific example of a method for driving the display device 10 will be described with reference to FIG. 13. The example illustrated in FIG. 13 is an example in which the organic EL layer 15 between the first cathode part 161 and the anode 13, that is, near the left, is caused to emit light in the first frame, and the organic EL layer 15 between the second cathode part 162 and the anode 13, that is, near the center, is caused to emit light in the next second frame. Note that it is not always necessary to change the light-emission portion in units of one frame, and the light-emission portion may be changed in units of several frames.

In the first frame, the scanning signal WS is sequentially input to the write transistors 26 included in the subpixels 101 arranged in the first line. The scanning signal WS is supplied to each of the FET 71B of the circuit part 71, the FET 72B of the circuit part 72, and the FET 73B of the circuit part 73, and each FET is turned on.

The pulse generation circuit 71A supplies a logically high-level signal to the inverter circuit 71C. Thereby, the FET 71D is turned off, the FET 71E is turned on, and Vcath is applied to the first cathode part 161 through the first wiring 161A. Hence a potential difference is generated between the first cathode part 161 and the anode 13, whereby the organic EL layer 15 interposed between the first cathode part 161 and the anode 13 emits light.

The pulse generation circuit 72A supplies a logically low-level signal to the inverter circuit 72C. Thereby, the FET 72D is turned on, the FET 72E is turned off, and Vano is applied to the second cathode part 162 through the second wiring 162A. Hence no potential difference is generated between the second cathode part 162 and the anode 13, and the organic EL layer 15 interposed between the second cathode part 162 and the anode 13 does not emit light.

The pulse generation circuit 73A supplies a logically low-level signal to the inverter circuit 73C. Thereby, the FET 73D is turned on, the FET 73E is turned off, and Vano is applied to the third cathode part 163 through the third wiring 163A. Hence no potential difference is generated between the third cathode part 163 and the anode 13, and the organic EL layer 15 interposed between the third cathode part 163 and the anode 13 does not emit light. In one frame period, the circuit parts 71, 72, 73 in each line operate similarly.

In the next second frame, the scanning signal WS is sequentially input to the write transistors 26 included in the subpixels 101 arranged in the first line. The scanning signal WS is supplied to each of the FET 71B of the circuit part 71, the FET 72B of the circuit part 72, and the FET 73B of the circuit part 73 in the first line, and each FET is turned on.

The pulse generation circuit 71A supplies a logically low-level signal to the inverter circuit 71C. Thereby, the FET 71D is turned on, the FET 71E is turned off, and Vano is applied to the first cathode part 161 through the first wiring 161A. Hence no potential difference is generated between the first cathode part 161 and the anode 13, and the organic EL layer 15 interposed between the first cathode part 161 and the anode 13 does not emit light.

The pulse generation circuit 72A supplies a logically high-level signal to the inverter circuit 72C. Thereby, the FET 72D is turned off, the FET 72E is turned on, and Vcath is applied to the second cathode part 162 through the second wiring 162A. Hence a potential difference is generated between the second cathode part 162 and the anode 13, whereby the organic EL layer 15 interposed between the second cathode part 162 and the anode 13 emits light.

The pulse generation circuit 73A supplies a logically low-level signal to the inverter circuit 73C. Thereby, the FET 73D is turned on, the FET 73E is turned off, and Vano is applied to the third cathode part 163 through the third wiring 163A. Hence no potential difference is generated between the third cathode part 163 and the anode 13, and the organic EL layer 15 interposed between the third cathode part 163 and the anode 13 does not emit light. The above operation is repeated.

(Control Corresponding to Line-of-Sight Direction)

Control may be exercised over a portion to be caused to emit light in accordance with the line-of-sight direction detected by the sensor 80. This enables the luminance in the front direction to be maintained as much as possible even in a case where the line-of-sight direction deviates from the front.

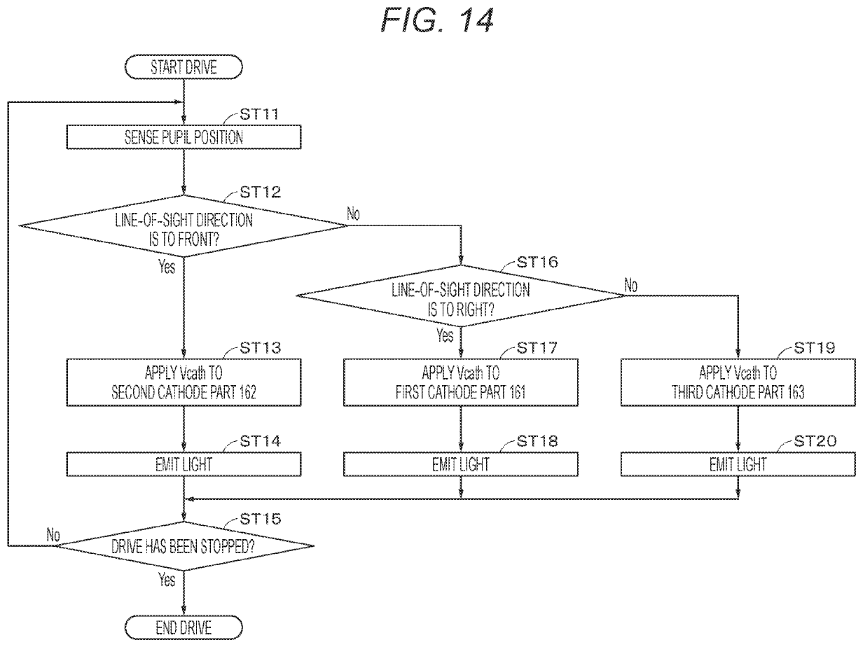

A specific example of the control corresponding to the line-of-sight direction will be described with reference to the flowchart illustrated in FIG. 14. The line-of-sight direction is detected by the sensor 80. In the present embodiment, the line-of-sight direction of the user is detected by detecting the pupil position of the user. The position and posture of the user may be detected by the sensor 80, and the line-of-sight direction of the user may be detected in accordance with the detection results.

For example, the drive control for the display device 10 is started at the timing when the power supply of the display device 10 is turned on. In step ST11, the pupil position of the user is sensed by the sensor 80. The sensing by the sensor 80 is performed, for example, in units of one frame. Naturally, the sensing cycle can be set as appropriate, such as units of several frames. A sensing result by the sensor 80 is supplied to the controller 90. Then, the processing proceeds to step ST12.

The controller 90 causes the display device 10 to detect the line-of-sight direction of the user on the basis of the sensing result of the sensor 80. Then, in step ST12, the controller 90 determines whether or not the line-of-sight direction is to the front. For example, a range in which the line-of-sight direction is determined to be to the front, right, or left is set in advance. As a specific example, when the front is set to 0°, it is determined that the line-of-sight direction is to the front in the range of −5° to 5°, that the line-of-sight direction is to the right in the range of an angle larger than 5° to 90°, and that the line-of-sight direction is to the left in the range of an angle greater than −5° to −90°. On the basis of this range and the detection result of the line-of-sight direction, the controller 90 determines whether or not the line-of-sight direction is to the front. In a case where the line-of-sight direction is to the front (in the case of Yes), the processing moves on to step ST13.

In step ST13, the controller 90 instructs the light-emission control circuit 70 to apply Vcath to the second cathode part 162 and apply Vano to each of the first cathode part 161 and the third cathode part 163. In accordance with the control of the controller 90, the light-emission control circuit 70 outputs a high-level signal from the pulse generation circuit 72A and applies Vcath to the second cathode part 162 through the second wiring 162A. Further, the light-emission control circuit outputs a low-level signal from each of the pulse generation circuits 71A and 73A. Thereby, the light-emission control circuit 70 applies Vano to the first cathode part 161 through the first wiring 161A and applies Vano to the third cathode part 163 through the third wiring 163A. Then, the processing proceeds to step ST14.

In step ST14, the vicinity of the front of the subpixel 101, in other words, an area corresponding to the line-of-sight direction, emits light. That is, as a result of the processing in step ST13, a potential difference is generated between the second cathode part 162 and the anode 13, so that a current flows, and the vicinity of the front surface in the subpixel 101 emits light. By performing similar processing on all the subpixels 101 in one frame period, the vicinity of the front of each of all the subpixels 101 emits light in one frame period. Then, the processing proceeds to step ST15.

In step ST15, it is determined whether or not the drive of the display device 10 has been stopped, such as whether or not the power of the display device 10 has been turned off. In a case where the drive has been stopped (in the case of Yes), the drive control for the display device 10 is ended. In a case where the drive has not been stopped (in the case of No), the processing proceeds to step ST11, and the pupil position in the next frame period is sensed.

In a case where the line-of-sight direction is not to the front in the determination processing of step ST12 (in the case of No), the processing proceeds to step ST16. Then, in step ST16, the controller 90 determines whether or not the line-of-sight direction is to the right. In a case where the line-of-sight direction is to the right (in the case of Yes), the processing proceeds to step ST17.

In step ST17, the controller 90 instructs the light-emission control circuit 70 to apply Vcath to the first cathode part 161 and apply Vano to the second cathode part 162 and the third cathode part 163. In accordance with the control of the controller 90, the light-emission control circuit 70 outputs a high-level signal from the pulse generation circuit 71A and applies Vcath to the first cathode part 161 through the first wiring 161A. Further, the light-emission control circuit 70 outputs a low-level signal from each of the pulse generation circuits 72A and 73A. Thereby, the light-emission control circuit 70 applies Vano to the second cathode part 162 through the second wiring 162A and applies Vano to the third cathode part 163 through the third wiring 163A. Then, the processing proceeds to step ST18.

In step ST18, the vicinity of the left of the subpixel 101 emits light. That is, as a result of the processing in step ST17, a potential difference is generated between the first cathode part 161 and the anode 13, so that a current flows, and the vicinity of the left in the subpixel 101 emits light. By performing similar processing on all the subpixels 101 in one frame period, the vicinity of the left of all the subpixels 101 emits light in one frame period. Then, the processing proceeds to step ST15. Since the contents of the processing related to step ST15 have been described, a redundant description will be omitted.

In a case where the line-of-sight direction is not to the right (in the case of No) in the determination processing of step ST16, the controller 90 determines that the line-of-sight direction is to the left. Then, the processing proceeds to step ST19.

In step ST19, the controller 90 instructs the light-emission control circuit 70 to apply Vcath to the third cathode part 163 and apply Vano to the first cathode part 161 and the second cathode part 162. In accordance with the control of the controller 90, the light-emission control circuit 70 outputs a high-level signal from the pulse generation circuit 73A and applies Vcath to the third cathode part 163 through the third wiring 163A. Further, the light-emission control circuit 70 outputs a low-level signal from each of the pulse generation circuits 71A and 72A. Thereby, the light-emission control circuit 70 applies Vano to the first cathode part 161 through the first wiring 161A and applies Vano to the second cathode part 162 through the second wiring 162A. Then, the processing proceeds to step ST20.

In step ST20, the vicinity of the right of the subpixel 101 emits light. That is, as a result of the processing in step ST19, a potential difference is generated between the third cathode part 163 and the anode 13, so that a current flows, and the vicinity of the right in the subpixel 101 emits light. By performing similar processing on all the subpixels 101 in one frame period, light is emitted in the vicinity of the right of all the subpixels 101 in one frame period. Then, the processing proceeds to step ST15. Since the contents of the processing related to step ST15 have been described, a redundant description will be omitted.

Note that in the processing described above, the detection processing of the line-of-sight direction may be performed by the display device 10. In addition, in a case where there is a plurality of users, the line-of-sight direction may be detected for each user, and light-emission control corresponding to the detection result may be performed. In the case of there being a plurality of users, there may be a case where the vicinity of the center and the vicinity of the left in the subpixel 101 emit light, a case where the vicinity of the center and the vicinity of the right emit light, and some other case.

### Effects Obtained by Present Embodiment

According to the present embodiment, for example, since the light-emission control corresponding to the line-of-sight direction is performed, it is possible to minimize a decrease in luminance even in a case where the user obliquely views the display device 10.

FIGS. 15A and 15B illustrate results of simulation of how a viewing angle characteristic (a luminance characteristic with respect to a viewing angle) changes in a case where the light-emission position in the subpixel is changed. FIGS. 16A and 16B illustrates results of similar simulation. However, FIGS. 15A and 15B are results of simulation in a case where there is a lens array, and FIGS. 16A and 16B are results of simulation in a case where there is no lens array. The simulation was performed by a finite-difference time-domain (FDTD) method.

An octagon illustrated in FIG. 15A indicates a subpixel, and a plurality of circles inside the octagon indicates portions to be caused to emit light. The simulation was performed by causing two portions surrounded by thick circles (two portions at the center and the end portion) among the plurality of portions to emit light. As a result, as illustrated in FIG. 15B, the peak of the luminance changed around −10° in a case where the end portion was caused to emit light. In addition, also in a case where the light-emission portion was changed in a similar manner to in FIG. 15A as illustrated in FIG. 16A, the peak of the luminance changed around −10° in a case where the end portion was caused to emit light as illustrated in FIG. 16B. That is, it was confirmed by simulation that the peak of the luminance can be shifted in a case where the light-emission portion in the subpixel is changed, and it can thus be said that the present technology of changing the light-emission portion in the subpixel is effective.

### Modification

Although the embodiment of the present disclosure has been described above, the present disclosure is not limited to the embodiment described above, and various modifications can be made without departing from the gist of the present disclosure.

### Modification 1

The light-emitting element 22 of each of the subpixels 101R, 101G, 101B may have a resonator structure (cavity structure). The resonator structure includes the metal layer 13A as a reflector and the first, second, and third cathode parts 161, 162, 163. The resonator structure resonates and emphasizes light of a specified wavelength corresponding to each color of the subpixels 101R, 101G, 101B and emits the light toward the display surface. Specifically, the resonator structure of the subpixel 101R resonates and emphasizes red light contained in white light generated in the organic EL layer 15 and emits the red light toward the display surface. The resonator structure of the subpixel 101G resonates and emphasizes green light contained in white light generated in the organic EL layer 15 and emits the green light toward the display surface. The resonator structure of the subpixel 101B resonates and emphasizes blue light contained in the white light generated in the organic EL layer 15 and emits the blue light toward the display surface.

An optical path length (optical distance) between the metal layer 13A and the first cathode part 161, an optical path length between the metal layer 13A and the second cathode part 162, and an optical path length between the metal layer 13A and the third cathode part 163 (hereinafter, in a case where these three optical path lengths are collectively referred to, the optical path lengths are referred to as an “optical path length between the metal layer and the cathode part”) are set to the same optical path length. The optical path length between the metal layer and the cathode part is set in accordance with the light of the specified wavelength resonated in each of the subpixels 101R, 101G, 101B. More specifically, in the resonator structure of the subpixel 101R, the optical path length between the metal layer and the cathode is set so that red light resonates and is emphasized. In the resonator structure of the subpixel 101G, the optical path length between the metal layer and the cathode part is set so that green light resonates and is emphasized. In the resonator structure of the subpixel 101B, the optical path length between the metal layer and the cathode is set so that blue light resonates and is emphasized.

The optical path length between the metal layer and the cathode part may be set by further providing an optical path length adjustment layer (not illustrated) between the metal layer 13A and the transparent conductive layer 13B and adjusting the thickness of the optical path length adjustment layer for each of the subpixels 101R, 101G, 101B. Alternatively, the optical path length between the metal layer and the cathode part may be set by adjusting the thickness of the metal layer 13A or the transparent conductive layer 13B for each of the subpixels 101R, 101G, 101B. The thicknesses of two or more of the optical path length adjustment layer, the metal layer 13A, and the transparent conductive layer 13B may be adjusted for each of the subpixels 101R, 101G, 101B.

### Modification 2

In the embodiment described above, an example has been described where a method of combining the white light-emitting element 22 and the color filter 18 is used as a coloring method, but the coloring method is not limited thereto. For example, an RGB coloring method or a method of extracting RGB trichromatic light by the resonator structure may be used. Further, a monochromatic filter may be used instead of the color filter 18.

### Modification 3

In the embodiment described above, the number of cathode parts is not limited to three but may be two or may be four or more. Wiring is connected to each cathode part. In a case where there are two cathode parts, two cathode parts are provided on the left and right.

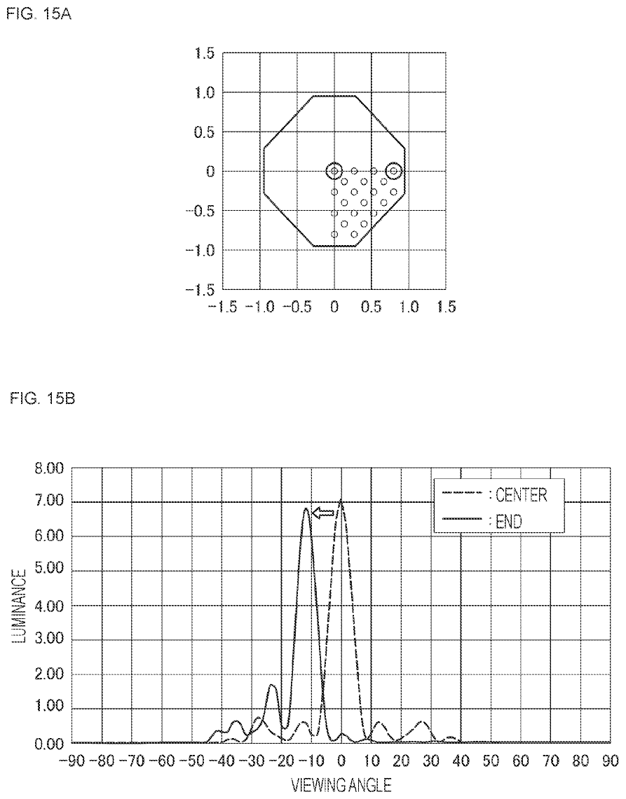

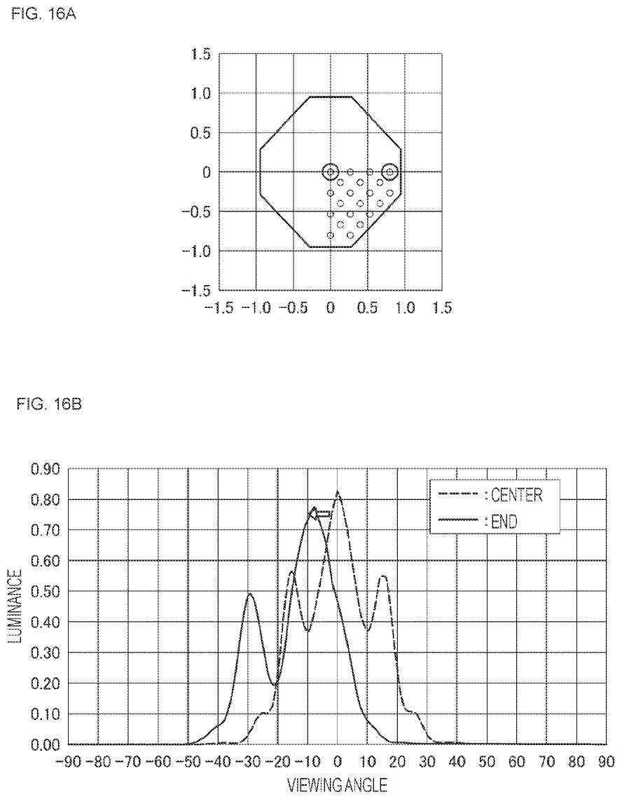

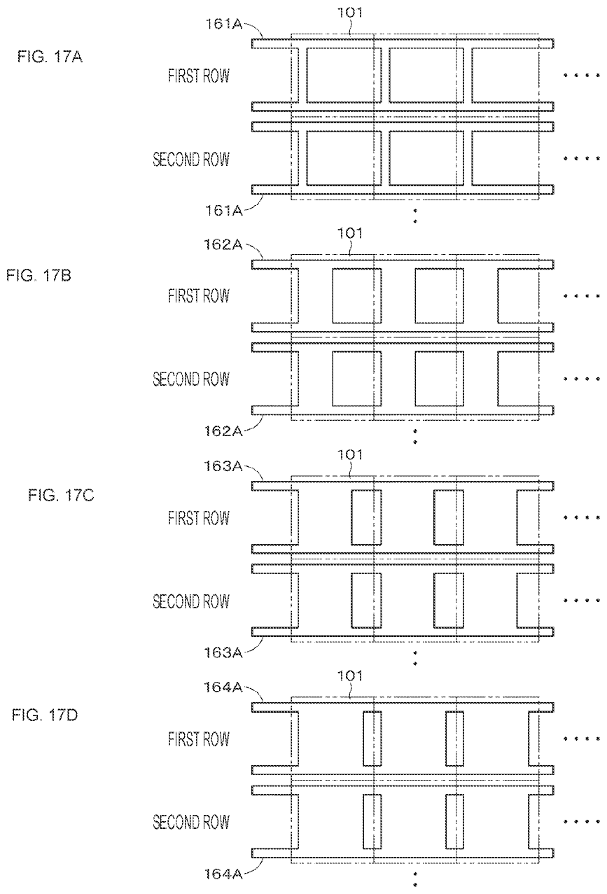

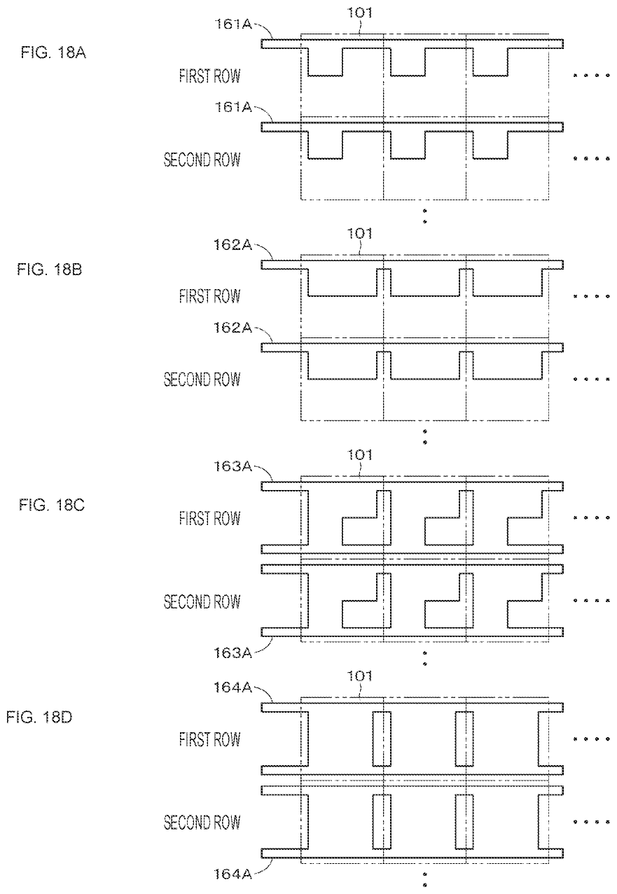

FIGS. 17 and 18 illustrate shape examples of wirings in a case where there are four cathode parts. For example, in addition to the first wiring 161A, the second wiring 162A, and the third wiring 163A of the embodiment, a fourth wiring 164A is provided in a layer different from each wiring. In each wiring, a via is appropriately provided, or a shape is appropriately set so that the wirings do not contact each other.

### Other Modifications

In the embodiment, the light-emission control corresponding to the detection result of the line-of-sight direction has been performed. However, light-emission control may be performed without considering the line-of-sight direction, and the display device may have a configuration without a sensor. For example, in the embodiment, portions of two cathode parts out of the three cathode parts may emit light. The light-emission portion can be switched at an appropriate timing. It is thereby possible to realize low power consumption of the display device and to prolong the life of the organic EL layer.

The two-dimensional arrangement of the pixels and the subpixels may be a two-dimensional arrangement in a matrix called a delta type. The anode may be divided instead of the cathode, or both may be divided. Further, the present disclosure can be realized by any form such as a device, a method, and a program. In addition, the matters described in each embodiment and modification can be combined as appropriate. Further, the contents of the present disclosure are not to be construed as being limited by the effects exemplified in the present specification. Moreover, for example, the configurations, methods, processes, shapes, materials, numerical values, and the like described in the embodiment and the modifications thereof are merely examples, and different configurations, methods, processes, shapes, materials, numerical values, and the like may be used as necessary.

### Application Example

(Electronic Device)

The display device according to each of the embodiment and the modifications thereof described above may be provided in various electronic devices. In particular, the display device is preferably provided in one for use in an electronic viewfinder for a video camera or a single-lens reflex camera, a head-mounted display, or the like that requires high resolution and is magnified close to the eye.

### Specific Example 1

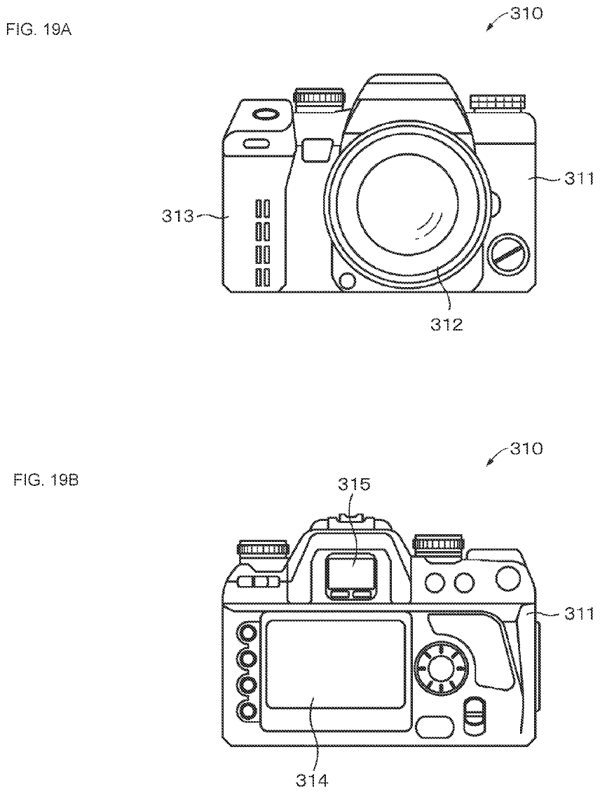

FIGS. 19A and 19B illustrate an example of an appearance of a digital still camera 310. The digital still camera 310 is of a lens-interchangeable single-lens reflex type and includes an interchangeable taking lens unit (interchangeable lens) 312 substantially at the center in front of a camera body 311, and a grip 313 to be held by a photographer on the front left side.

A monitor 314 is provided at a position off to the left from the center of the back surface of the camera body 311. An electronic viewfinder (eyepiece window) 315 is provided above the monitor 314. By looking into the electronic viewfinder 315, the photographer can view the optical image of the subject guided from the taking lens unit 312 to determine the composition. As the electronic viewfinder 315, for example, the display device 10 can be applied.

### Specific Example 2

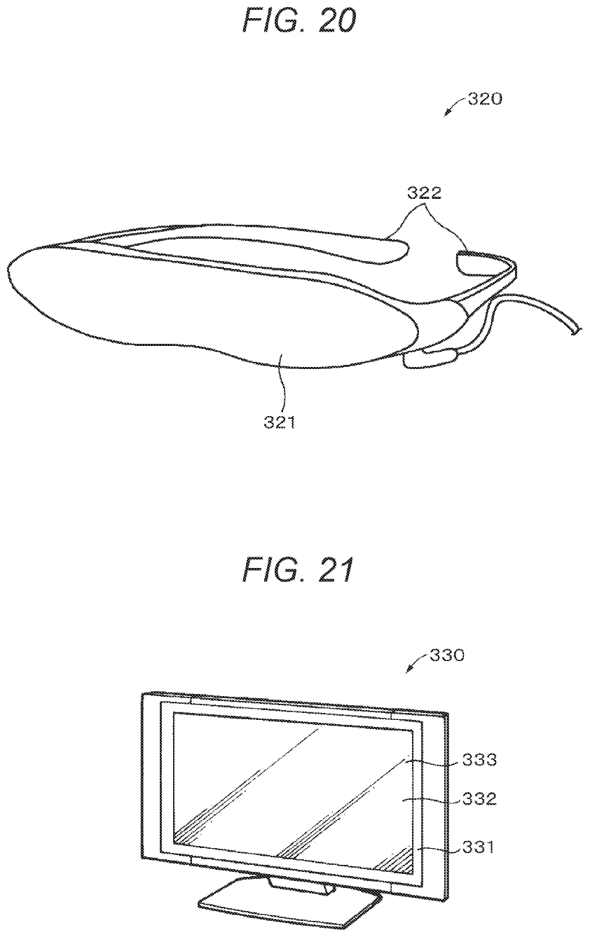

FIG. 20 illustrates an example of an appearance of a head-mounted display 320. The head-mounted display 320 includes, for example, an ear hook 322 to be mounted on the head of a user on both sides of a glass-shaped display part 321. As the display part 321, for example, the display device 10 can be applied.

### Specific Example 3

FIG. 21 illustrates an example of an appearance of a television device 330. The television device 330 includes, for example, a video display screen part 331 including a front panel 332 and a filter glass 333, and as the video display screen part 331, for example, the display device 10 can be applied.

Further, the present disclosure can adopt the following configurations.

(1)

A display device including pixel parts arranged two-dimensionally,
in which
each of the pixel parts includes
a first electrode,
a second electrode provided to face the first electrode and divided into a plurality of electrode parts, and
an electroluminescent layer provided between the first electrode and the second electrode.

(2)

The display device according to (1), in which
the pixel part includes a plurality of wiring parts provided in different layers, and
the plurality of electrode parts is respectively connected to the wiring parts that are different from each other.

(3)

The display device according to (2), further including a light-emission control circuit that applies a first voltage or a second voltage different from the first voltage to each of the plurality of wiring parts.

(4)

The display device according to (3), in which the light-emission control circuit applies the first voltage or the second voltage to each of the plurality of wiring parts in accordance with a result of sensing by a sensor.

(5)

The display device according to (4), in which the first voltage is the same voltage as the voltage applied to the first electrode, and the second voltage is a voltage different from the voltage applied to the first electrode.

(6)

The display device according to (5), in which
the sensor is a sensor that detects a line-of-sight direction of a user, and
the light-emission control circuit applies the second voltage to the wiring part connected to the electrode part corresponding to the line-of-sight direction and applies the first voltage to the wiring part connected to another of the electrode parts.

(7)

The display device according to any one of (4) to (6), further including the sensor.

(8)

The display device according to any one of (2) to (7), in which the plurality of wiring parts is provided for each of lines.

(9)

The display device according to any one of (3) to (7), in which
the light-emission control circuit has a configuration where a circuit part with a switching element and an inverter circuit directly connected to each other is provided for each of the electrode parts of the second electrode, and
an output of the inverter circuit is connected to the electrode part.

(10)

The display device according to (9), in which the same signal as a signal of a video signal write transistor is supplied to the switching element.

(11)

An electronic device including the display device according to any one of (1) to (10).

(12)

A method for driving a display device that includes pixel parts arranged two-dimensionally, each of the pixel parts including a first electrode, a second electrode provided to face the first electrode and divided into a plurality of electrode parts, and an electroluminescent layer provided between the first electrode and the second electrode,
the method including applying a first voltage that is the same voltage as a voltage applied to the first electrode, or a second voltage that is a voltage different from the voltage applied to the first electrode, to each of the plurality of electrode parts.

(13)

The method for driving the display device according to (12), in which
the pixel part includes a plurality of wiring parts provided in different layers,
the plurality of electrode parts is respectively connected to the wiring parts that are different from each other, and
the light-emission control circuit applies the first voltage or the second voltage to each of the plurality of wiring parts.

(14)

The method for driving the display device according to (13), in which the light-emission control circuit applies the first voltage or the second voltage to each of the plurality of wiring parts in accordance with a result of sensing by a sensor.

### REFERENCE SIGNS LIST

10 Display device
13 Anode
15 Organic EL layer
16 Cathode
70 Light-emission control circuit
71B, 72B, 73B FET
71C, 72C, 73C Inverter circuit
80 Sensor
101 Subpixel
161, 162, 163 First cathode part, second cathode part, third cathode part
161A, 162A, 163A First wiring, second wiring, third wiring

1. A display device comprising pixel parts arranged two-dimensionally,
wherein
each of the pixel parts includes
a first electrode,
a second electrode provided to face the first electrode and divided into a plurality of electrode parts, and
an electroluminescent layer provided between the first electrode and the second electrode.

2. The display device according to claim 1, wherein
the pixel part includes a plurality of wiring parts provided in different layers, and
the plurality of electrode parts is respectively connected to the wiring parts that are different from each other.

3. The display device according to claim 2, further comprising a light-emission control circuit that applies a first voltage or a second voltage different from the first voltage to each of the plurality of wiring parts.

4. The display device according to claim 3, wherein the light-emission control circuit applies the first voltage or the second voltage to each of the plurality of wiring parts in accordance with a result of sensing by a sensor.

5. The display device according to claim 4, wherein the first voltage is the same voltage as the voltage applied to the first electrode, and the second voltage is a voltage different from the voltage applied to the first electrode.

6. The display device according to claim 5, wherein
the sensor is a sensor that detects a line-of-sight direction of a user, and
the light-emission control circuit applies the second voltage to the wiring part connected to the electrode part corresponding to the line-of-sight direction and applies the first voltage to the wiring part connected to another of the electrode parts.

7. The display device according to claim 4, further comprising the sensor.

8. The display device according to claim 2, wherein the plurality of wiring parts is provided for each of lines.

9. The display device according to claim 3, wherein
the light-emission control circuit has a configuration in which a circuit part with a switching element and an inverter circuit directly connected to each other is provided for each of the electrode parts of the second electrode, and
an output of the inverter circuit is connected to the electrode part.

10. The display device according to claim 9, wherein the same signal as a signal of a video signal write transistor is supplied to the switching element.

11. An electronic device comprising the display device according to claim 1.

12. A method for driving a display device that includes pixel parts arranged two-dimensionally, each of the pixel parts including a first electrode, a second electrode provided to face the first electrode and divided into a plurality of electrode parts, and an electroluminescent layer provided between the first electrode and the second electrode,
the method comprising applying a first voltage that is the same voltage as a voltage applied to the first electrode, or a second voltage that is a voltage different from the voltage applied to the first electrode, to each of the plurality of electrode parts.

13. The method for driving the display device according to claim 12, wherein
the pixel part includes a plurality of wiring parts provided in different layers,
the plurality of electrode parts is respectively connected to the wiring parts that are different from each other, and
the light-emission control circuit applies the first voltage or the second voltage to each of the plurality of wiring parts.

14. The method for driving the display device according to claim 13, wherein the light-emission control circuit applies the first voltage or the second voltage to each of the plurality of wiring parts in accordance with a result of sensing by a sensor.
